(19) United States
(12) Patent Application Publication
(10) Pub. No.: US 2025/0047288 A1
(43) Pub. Date: Feb. 6, 2025

(54) TRANSMISSION DEVICE, TRANSMISSION/RECEPTION SYSTEM, AND METHOD FOR CONTROLLING TRANSMISSION DEVICE

(71) Applicant: SONY SEMICONDUCTOR SOLUTIONS CORPORATION, KANAGAWA (JP)

(72) Inventors: SATOSHI FUKUDA, KANAGAWA (JP); TOMOHIRO MATSUMOTO, KANAGAWA (JP)

(21) Appl. No.: 18/710,693

(22) PCT Filed: Sep. 29, 2022
(86) PCT No.: PCT/JP2022/036458

§ 371 Date: May 16, 2024

(30) Foreign Application Priority Data
Nov. 24, 2021 (JP) 2021-190043

(51) Int. Cl. H03L 7/08; H04B 1/04; H04L 7/033

(52) U.S. Cl. CPC H03L 7/08; H04B 1/04; H04L 7/033

(57) ABSTRACT

In a system that transmits and receives data, the correction of the frequency of a clock signal is less frequently performed. A clock signal generation unit generates a transmission clock signal. A transmission unit transmits the transmission clock signal. An error acquisition unit acquires an external measurement error that is an error in a frequency of a reception clock signal measured by a reception device that receives the transmission clock signal and generates the reception clock signal from the transmission clock signal. A frequency control unit controls a frequency of the transmission clock signal based on the external measurement error and a measurement value measured on a transmission side.

### TECHNICAL FIELD

The present technology relates to a transmission device Specifically, the present invention relates to a transmission device that transmits data, a transmission/reception system, and a method for controlling the transmission device.

### BACKGROUND ART

In wired communication, a reception device can correctly receive transmitted data by aligning the phase of received data with the phase of a reception clock. In order to align the phases of the data and clock, the transmission frequency and the reception frequency need to match each other or the error between them needs to be extremely small. A transmission/reception system (see PTL 1, for example) does not include a reference oscillator on the transmission side for the purpose of downsizing. On the other hand, the reception device includes a reference oscillator, and is thus configured to compare the received clock with the reference clock and return the error information to the transmission system so that the frequencies of the transmission and reception systems match each other or the error in frequency is reduced.

### Citation List

### Patent Literature

### PTL 1

WO 2020/070974

### SUMMARY

### Technical Problem

In the above-described conventional technology, the transmission device corrects the frequency based on the error information from the reception device, thereby preventing transmission errors. However, since the frequency of the clock signal generally fluctuates in response to changes in temperature and power supply voltage, there is a problem in that the faster the rate of the changes, the more frequently the correction of the frequency is to be performed.

The present technology has been devised in view of such circumstances and an object thereof is to reduce the frequency of correction of the frequency of a clock signal in a system that transmits and receives data.

### Solution to Problem

The present technology has been made to solve the above-described problem, and a first aspect thereof is a transmission device including: a transmission clock signal generation unit that generates a transmission clock signal; a transmission unit that transmits the transmission clock signal; an error acquisition unit that acquires an external measurement error that is an error in a frequency of a reception clock signal measured by a reception device that receives the transmission clock signal and generates the reception clock signal from the transmission clock signal; and a frequency control unit that controls a frequency of the transmission clock signal based on the external measurement error and a measurement value measured on a transmission side, and a method for controlling the transmission device. This provides an effect that the correction of the frequency is less frequently performed.

In this first aspect, the transmission unit may include a driver that embeds the transmission clock signal in data and transmits the data. This provides an effect that the number of signal lines is reduced.

In this first aspect, the transmission unit may include a first driver that transmits data and a second driver that transmits the transmission clock signal. This provides a effect that a clock data recovery circuit is not required.

In this first aspect, the transmission clock signal generation unit may be an all digital phase-locked loop (ADPLL) that multiplies a master clock signal, and the frequency control unit may include a correction coefficient holding unit that holds a predetermined number of correction coefficients, a frequency control word generation unit that generates, based on the measurement value and the held correction coefficients, a frequency control word indicating a multiplication ratio of the ADPLL, and a control circuit that updates the held correction coefficients based on the external measurement error. This provides an effect that the multiplication ratio is updated.

In this first aspect, the measurement value may include at least one of a temperature, a power supply voltage, and a voltage or a current that indicates process information. This provides an effect that frequency fluctuation due to changes in temperature and power supply voltage are corrected.

In this first aspect, the measurement value may include an actual measurement frequency of the transmission clock signal measured on the transmission side, and the control circuit may set initial values for the correction coefficients based on the actual measurement frequency. This provides an effect that frequency fluctuation due to changes in temperature and power supply voltage are corrected.

In this first aspect, the control circuit may update the held correction coefficients when the external measurement error is outside a predetermined range, and the frequency control word generation unit may update the frequency control word when the correction coefficients are updated. This provides an effect that the external measurement error is controlled within an allowable range.

In this first aspect, a startup oscillator may be further included that generates a predetermined startup clock signal when a startup signal from the reception device is detected, and the frequency control unit may control the transmission clock signal generation unit in synchronization with the startup clock signal. This provides an effect that the transmission clock signal generation unit is easily started up.

A second aspect of the present technology is a transmission/reception system including: a reception device that receives a transmission clock signal, generates a reception clock signal from the transmission clock signal, and measures an error in a frequency of the reception clock signal as an external measurement error; and a transmission device that includes an error acquisition unit that acquires the external measurement error, a clock signal generation unit that generates a transmission clock signal, a transmission unit that transmits the transmission clock signal, and a frequency control unit that controls a frequency of the transmission clock signal based on the external measurement error and a measurement value measured on a transmission side. This provides an effect that the correction of the frequency is less frequently performed in the transmission/reception system.

In this second aspect, the transmission unit may include a first driver that embeds the transmission clock signal in data and transmits the data, and the reception device may include a third driver that receives the data and a clock data recovery circuit that extracts the transmission clock signal from the received data. This provides an effect that the number of signal lines is reduced.

In this second aspect, the transmission unit may include a first driver that transmits data and a second driver that transmits the transmission clock signal, and the reception device may include a first receiver that receives the data and a second receiver that receives the transmission clock signal. This provides a effect that a clock data recovery circuit is not required.

### BRIEF DESCRIPTION OF DRAWINGS

FIG. 1 is a block diagram illustrating a configuration example of a transmission/reception system and a transmission device according to a first embodiment of the present technology.

FIG. 2 is a block diagram illustrating a configuration example of a reception device according to the first embodiment of the present technology.

FIG. 3 is a block diagram illustrating a configuration example of a data transmission unit and a master clock generation unit according to the first embodiment of the present technology.

FIG. 4 is a block diagram illustrating a configuration example of a frequency control unit according to the first embodiment of the present technology.

FIG. 5 is a block diagram illustrating a configuration example of an all digital phase-locked loop (ADPLL) according to the first embodiment of the present technology.

FIG. 6 is a flowchart illustrating an example of an operation of the transmission device according to the first embodiment of the present technology.

FIG. 7 is a flowchart illustrating an example of frequency correction processing according to the first embodiment of the present technology.

FIG. 8 is a graph illustrating an example of temperature characteristics of a master clock signal and a transmission clock signal according to the first embodiment of the present technology.

FIG. 9 illustrates an example of frequency fluctuation and temperature fluctuation of a transmission clock signal according to the first embodiment of the present technology.

FIG. 10 illustrates an example of error fluctuation and temperature fluctuation according to the first embodiment of the present technology.

FIG. 11 illustrates an example of error fluctuation and temperature fluctuation according to a comparative example.

FIG. 12 illustrates a method for determining initial values for correction coefficients according to the first embodiment of the present technology.

FIG. 13 is a block diagram illustrating a configuration example of a transmission device according to a second embodiment of the present technology.

FIG. 14 is a block diagram illustrating a configuration example of a reception device according to the second embodiment of the present technology.

FIG. 15 is a block diagram illustrating a configuration example of an imaging device according to an embodiment of the present technology.

FIG. 16 is a block diagram illustrating a schematic configuration example of a vehicle control system.

FIG. 17 is an explanatory diagram illustrating an example of installation positions of imaging units.

FIG. 18 is a block diagram illustrating an example of a schematic configuration of an in-body information acquisition system.

### DESCRIPTION OF EMBODIMENTS

Modes for carrying out the present technology (hereinafter also referred to as “embodiments”) will be described below. The description will be given in the following order.
1. First Embodiment (Example of Performing Internal Correction and External Correction Using Clock-Embedded Method)
2. Second Embodiment (Example of Performing Internal Correction and External Correction Using Source Synchronous Method)
3. Example of Application to Moving Body
4. Example of Application to In-body Information Acquisition System

### 1. First Embodiment

### Configuration Example of Transmission/Reception System

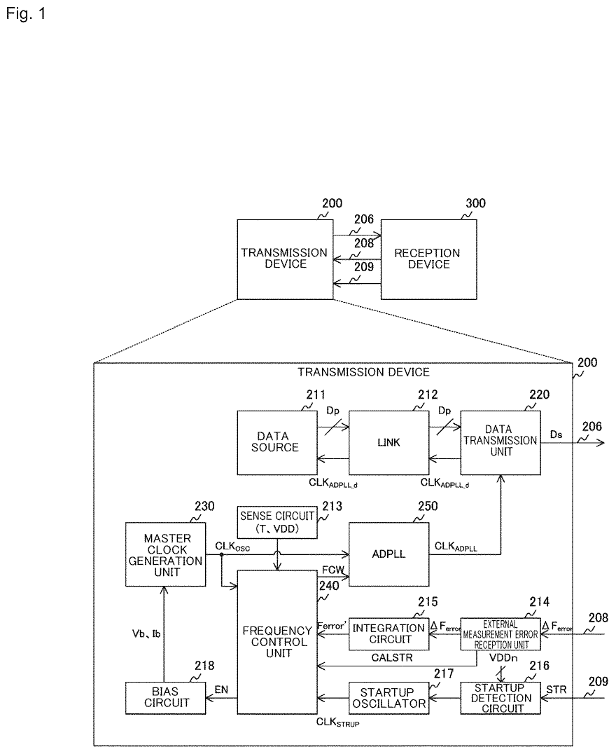

FIG. 1 is a block diagram illustrating a configuration example of a transmission/reception system and a transmission device 200 according to a first embodiment of the present technology. This transmission/reception system of the first embodiment transmits and receives data and a clock signal for synchronization between the transmission device 200 and a reception device 300. The transmission/reception system is applied to, for example, an imaging device or an in-body information acquisition system using an endoscope.

The transmission device 200 transmits data. In the figure, a clock-embedded method is used in which a clock signal is embedded in data and the resulting data is transmitted.

The transmission device 200 includes a data source 211, a link unit 212, a data transmission unit 220, a master clock generation unit 230, a frequency control unit 240, and an ADPLL 250. The transmission device 200 also includes a sense circuit 213, an external measurement error reception unit 214, an integration circuit 215, a startup detection circuit 216, a startup oscillator 217, and a bias circuit 218.

The data source 211 generates data Dp to be transmitted. This data source 211 supplies the generated data Dp to the link unit 212 in a parallel manner in synchronization with a frequency-divided clock signal CLK_{ADPLL_d}.

The link unit 212 performs predetermined processing on the data Dp from the data source 211, and supplies the processed data Dp to the data transmission unit 220 in a parallel manner in synchronization with the frequency-divided clock signal CLK_{ADPLL_d}.

The data transmission unit 220 transmits data Ds in a serial manner via a signal line 206 in synchronization with a transmission clock signal CLK_{ADPLL} from the ADPLL 250. This data transmission unit 220 performs parallel-to-serial conversion on the data Dp from the link unit 212 to generate the data Ds. The data transmission unit 220 also divides the frequency of the transmission clock signal CLK_{ADPLL}, and supplies the frequency-divided clock signal CLK_{ADPLL} a to the link unit 212.

Here, in the clock-embedded method, the transmission clock signal CLK_{ADPLL}, is embedded in the data Ds. This transmission clock signal CLK_{ADPLL} is extracted from the data Ds by the reception device 300. Then, in the reception device 300, a reception clock signal CLK_{ADPLL_R} (not illustrated) is generated from the transmission clock signal CLK_{ADPLL} by frequency division using the same frequency division ratio as that on the transmission side. The data transmission unit 220 is an example of a transmission unit described in the claims.

The sense circuit 213 measures a temperature T and supplies an analog signal indicating the resulting measurement value to the frequency control unit 240. The sense circuit 213 can also measure instead of the temperature T a power supply voltage VDD or a voltage or current value indicating process information. The sense circuit 213 can also measure all of the temperature T, the power supply voltage VDD, and the voltage or current value indicating process information.

The external measurement error reception unit 214 receives an external measurement error ΔFₑᵣᵣₒᵣ from the reception device 300 via a signal line 208. The external measurement error reception unit 214 supplies the received external measurement error ΔFₑᵣᵣₒᵣ to the integration circuit 215. When the external measurement error reception unit 214 first receives the external measurement error ΔFₑᵣᵣₒᵣ after the transmission device 200 starts up, the external measurement error reception unit 214 supplies to the frequency control unit 240 an external correction startup signal CALSTR for starting correction using the signal of the external measurement error ΔFₑᵣᵣₒᵣ. The external measurement error reception unit 214 is an example of an error acquisition unit described in the claims.

Here, the reception clock signal CLK_{ADPLL_R} is a signal having the same frequency as the frequency-divided clock signal CLK_{ADPLL} a on the transmission side. The reception device 300 measures an absolute error in the frequency of the reception clock signal CLK_{ADPLL_R} based on a reference clock signal INCK_{REF} as an absolute reference. This error is measured outside the transmission device 200 and corresponds to the above-mentioned external measurement error ΔFₑᵣᵣₒᵣ. The reception device 300 may measure an absolute error between the frequency of the reference clock signal INCK_{REF} and a frequency obtained by dividing the frequency of the reception clock signal CLK_{ADPLL}_R.

The integration circuit 215 integrates the external measurement error ΔFₑᵣᵣₒᵣ and supplies the resulting error to the frequency control unit 240 as Ferror′.

The startup detection circuit 216 starts up the startup oscillator 217 based on a startup signal STR from the reception device 300. This startup detection circuit 216 determines whether or not the startup signal STR is received from the reception device 300 via a signal line 209. When receiving the startup signal STR, the startup detection circuit 216 determines whether or not all the circuits in the transmission device 200 are powered on. When all the circuits are powered on, the startup detection circuit 216 starts up the startup oscillator 217.

The startup oscillator 217 generates a startup clock signal CLK_{STRUP}. This startup oscillator 217 supplies the generated startup clock signal CLK_{STRUP} to the frequency control unit 240.

The frequency control unit 240 controls the frequency of the transmission clock signal CLK_{ADPLL} based on a measurement value (temperature T, etc.) measured inside the transmission device 200 and an external measurement error F_{error′} measured outside. Details of the method for controlling the frequency will be described later.

The bias circuit 218 generates a predetermined bias voltage Vb or a predetermined bias current Ib and supplies it to the master clock generation unit 230.

The master clock generation unit 230 generates a master clock signal CLK_{OSC} and supplies it to the ADPLL 250.

The ADPLL 250 multiplies the master clock signal CLK_{OSC} to generate a transmission clock signal CLK_{ADPLL}. The multiplication ratio of this ADPLL 250 is controlled by a frequency control word FCW from the frequency control unit 240. The ADPLL 250 is an example of a clock signal generation unit described in the claims.

Although the transmission/reception system transmits clock signals using the clock-embedded method, the transmission/reception system may transmit clock signals using the source synchronous method, as will be described later.

### Configuration Example of Reception Device

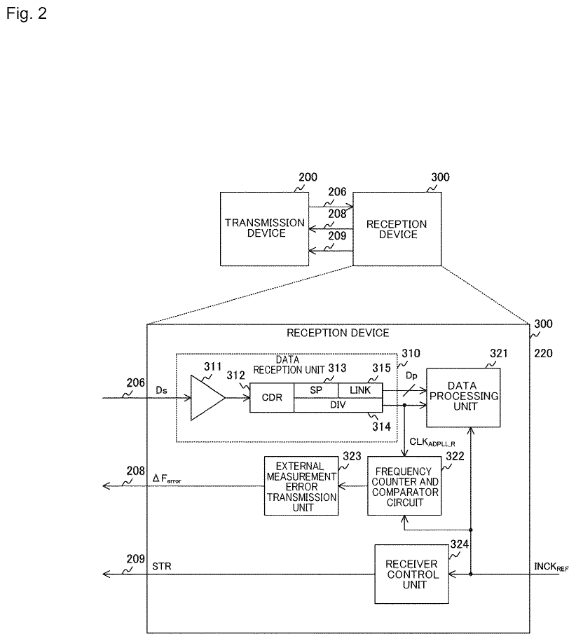

FIG. 2 is a block diagram illustrating a configuration example of the reception device 300 according to the first embodiment of the present technology. This reception device 300 receives data and includes a data reception unit 310, a data processing unit 321, a frequency counter and comparator circuit 322, an external measurement error transmission unit 323, and a receiver control unit 324.

The data reception unit 310 receives the data Ds via the signal line 206 in a serial manner. The data reception unit 310 includes a driver 311, a clock data recovery circuit 312, a serial-to-parallel converter 313, a frequency divider 314, and a link unit 315.

The driver 311 receives the data Ds and supplies it to the clock data recovery circuit 312.

The clock data recovery circuit 312 extracts the transmission clock signal CLK_{ADPLL} from the data Ds. This clock data recovery circuit 312 supplies the data Ds to the serial-to-parallel converter 313 and supplies the extracted transmission clock signal CLK_{ADPLL} to the frequency divider 314.

The serial-to-parallel converter 313 performs serial-to-parallel conversion on the data Ds. This serial-to-parallel converter 313 supplies the data Dp obtained by the conversion to the data processing unit 321 via the link unit 315 in a parallel manner.

The frequency divider 314 divides the frequency of the extracted transmission clock signal CLK_{ADPLL}. It is assumed that the frequency division ratio of the frequency divider 314 is the same as that on the transmission side. The frequency divider 314 supplies a clock signal generated by the frequency division as a reception clock signal CLK_{ADPLL_R} to the data processing unit 321 and the frequency counter and comparator circuit 322.

The data processing unit 321 processes the data Dp in synchronization with the reception clock signal CLK_{ADPLL} R.

The frequency counter and comparator circuit 322 calculates an error in the frequency F_{ADPLL_R} of the reception clock signal CLK_{ADPLL} R. The reference clock signal INCK_{REF} is input to the frequency counter and comparator circuit 322. The frequency FREF of this reference clock signal INCK_{REF} is set to an ideal value when there is no error in the frequency F_{ADPLL_R}. The frequency counter and comparator circuit 322 generates an external measurement error ΔFₑᵣᵣₒᵣ using the following expression, for example, and supplies it to the external measurement error transmission unit 323.

$$Δ {F}_{e r r o r} = {F}_{ADPLL \_ R} / {F}_{R E F} \qquad Expression 1$$

A frequency divider (not illustrated) may be provided inside the frequency counter and comparator circuit 322, and an absolute error between a frequency obtained by dividing the frequency of the reception clock signal CLK_{ADPLL_R} and the reference clock signal INCK_{REF} may be set as the external measurement error ΔFₑᵣᵣₒᵣ.

The external measurement error transmission unit 323 transmits the external measurement error ΔFₑᵣᵣₒᵣ to the transmission device 200 via the signal line 208.

The receiver control unit 324 generates a startup signal STR in controlling the reception device 300. This receiver control unit 324 transmits the startup signal STR to the transmission device 200 via the signal line 209.

### Configuration Example of Master Clock Generation Unit and Data Transmission Unit

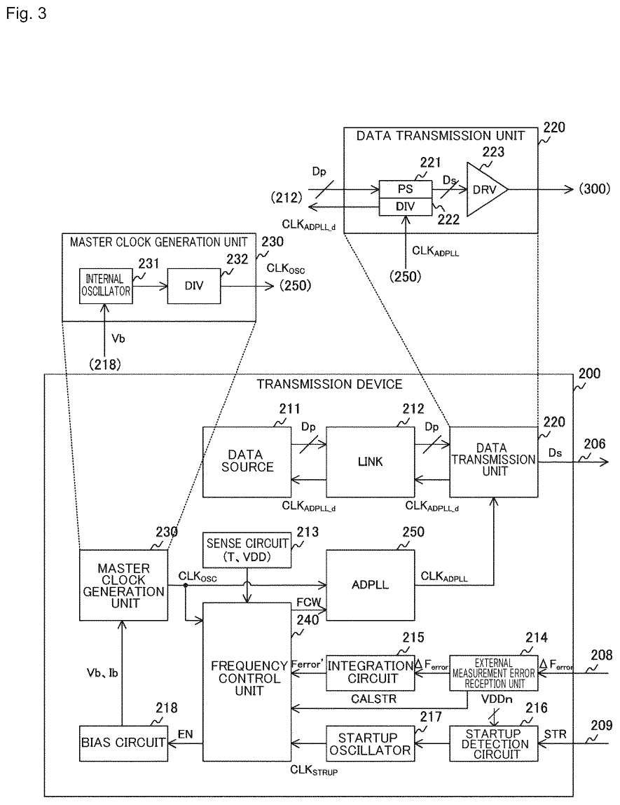

FIG. 3 is a block diagram illustrating a configuration example of the data transmission unit 220 and the master clock generation unit 230 according to the first embodiment of the present technology. The data transmission unit 220 includes a parallel-to-serial converter 221, a frequency divider 222, and a driver 223.

The parallel-to-serial converter 221 performs parallel-to-serial conversion on the data Dp from the link unit 212, and embeds the transmission clock signal CLK_{ADPLL} in the resulting data. This parallel-to-serial converter 221 supplies the data Ds obtained by the conversion to the driver 223 in a serial manner. This data Ds in a serial manner is, for example, differentially transmitted.

The frequency divider 222 divides the frequency of the transmission clock signal CLK_{ADPLL} from the ADPLL 250 to generate a frequency-divided clock signal CLK_{ADPLL_d}. This frequency divider 222 supplies the generated frequency-divided clock signal CLK_{ADPLL}, a to the link unit 212.

The driver 223 transmits the data Ds to the reception device 300 via the signal line 206 in a serial manner. The differentially transmitted data Ds is subjected to differential-to-single-ended conversion by the driver 223, and is then transmitted in a single-ended manner. A configuration may be provided in which the parallel-to-serial converter 221 transmits the data Ds in a single-end manner while the driver 223 does not perform differential-to-single-ended conversion.

The master clock generation unit 230 includes an internal oscillator 231 and a frequency divider 232. The internal oscillator 231 generates a clock signal with a frequency corresponding to the bias voltage Vb or the bias current Ib, and supplies the clock signal to the frequency divider 232. As the internal oscillator 231, for example, a voltage-controlled oscillator is used.

The frequency divider 232 divides the frequency of the clock signal from the internal oscillator 231 to generate a master clock signal CLK_{OSC}. This frequency divider 232 supplies the generated master clock signal CLK_{OSC} to the frequency control unit 240 and the ADPLL 250. After the above-described startup processing is completed, the frequency control unit 240 switches the clock serving as the reference for operation from CLK_{STRUP} to CLK_{OSC}.

### Configuration Example of Frequency Control Unit

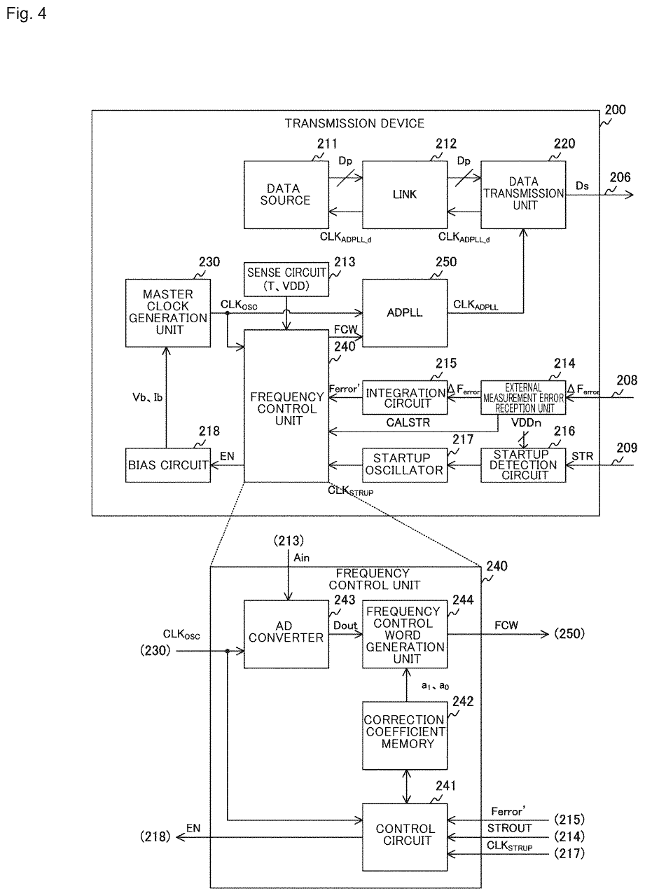

FIG. 4 is a block diagram illustrating a configuration example of the frequency control unit 240 according to the first embodiment of the present technology. This frequency control unit 240 includes a control circuit 241, a correction coefficient memory 242, an analog-to-digital (AD) converter 243, and a frequency control word generation unit 244.

The control circuit 241 performs processing for correcting the frequency. This control circuit 241 calculates an initial value(s) of a correction coefficient(s) based on a measurement value(s) of the frequency of the transmission clock signal CLK_{ADPLL} before the start of communication between the transmission device 200 and the reception device 300, and holds the initial value(s) in the correction coefficient memory 242 in advance. Here, the correction coefficient(s) are coefficient(s) used to calculate a frequency control word FCW. For example, two correction coefficients, a₁ and a₀, are held in the correction coefficient memory 242. The correction coefficient a₁ is used as a coefficient for the temperature T.

In response to the start of input of the startup clock signal CLK_{STRUP} from the startup oscillator 217, the control circuit 241 determines an initial value for a register that controls the master clock generation unit 230.

The control circuit 241 also starts up the bias circuit 218 using an enable signal EN.

Then, the control circuit 241 repeatedly acquires the external measurement error Ferror′ at predetermined periods in synchronization with the master clock signal CLK_{OSC}. Each time the external measurement error Ferror′ is acquired, the control circuit 241 determines whether or not the external measurement error Ferror′ is within a predetermined allowable range using the following expression.

$${a}_{0} \to {a}_{0} \cdot {Ferror}^{′} \qquad Expression 3$$

In the above expression, ΔF_{SPEC} is a constant value determined based on the required specifications of the transmission/reception system.

If Expression 2 is satisfied (e.g., the external measurement error Ferror′ is within the allowable range), the control circuit 241 either ends the communication or enters a waiting state.

On the other hand, if Expression 2 is not satisfied (e.g., the external measurement error Ferror′ is outside the allowable range), the control circuit 241 acquires the correction coefficient a₀) before update as a value held in the correction coefficient memory 242, and the external measurement error Ferror′.

$$1 - Δ {F}_{SPEC} < {Ferror}^{′} < 1 + Δ {F}_{SPEC} \qquad Expression 2$$

The left side in the above expression indicates a new correction coefficient after update. The right side indicates the result of multiplying the correction coefficient before update by the external measurement error Ferror′.

The control circuit 241 updates the correction coefficient a₀ in the correction coefficient memory 242 using Expression 3. The control circuit 241 controls the correction coefficient memory 242 every time the correction coefficient is updated, and causes the frequency control word generation unit 244 to output the updated correction coefficient.

The correction coefficient memory 242 holds the correction coefficients a₁ and a₀. The correction coefficient memory 242 is an example of a correction coefficient holding unit described in the claims.

The AD converter 243 converts an analog signal Ain from the sense circuit 213 into a digital signal Dout in synchronization with the master clock signal CLK_{OSC}, and supplies the digital signal Dout to the frequency control word generation unit 244. This digital signal Dout indicates the temperature T or the power supply voltage VDD, which is internally measured, or a voltage or current value indicating process information.

The frequency control word generation unit 244 generates a frequency control word FCW based on the measurement value (temperature T, etc.) indicated by the digital signal Dout and the correction coefficients. When the transmission device 200 is powered on, the frequency control word generation unit 244 reads the initial values of the correction coefficients a₁ and a₀ from the correction coefficient memory 242, and generates a frequency control word FCW using the following expression. K is a constant related to the multiplication ratio.

$$FCW = K / ( {a}_{1} \times T + {a}_{0} ) \qquad Expression 4$$

The denominator of Expression 4 is an estimated value of temperature characteristic of the master clock signal CLK_{OSC}. By multiplying the denominator of the frequency control word by the estimated value of temperature characteristic of the master clock signal CLK_{OSC} as an inverse function, the temperature characteristic at the frequency of the transmission clock signal CLK_{ADPLL} IS corrected. Every time the correction coefficient memory 242 is updated, the frequency control word generation unit 244 updates the frequency control word FCW using Expression 4 based on the updated correction coefficients and temperature T. The error in the frequency is corrected by updating the frequency control word FCW.

The initial value of the correction coefficient a₀ and the correction coefficient a₁ are determined based on the frequency of the transmission clock signal CLK_{ADPLL} measured within the transmission device 200. Accordingly, these values are referred to as “internal correction coefficients”. The correction of a frequency using only these internal correction coefficients and internally measurement values (temperature, etc.) is referred to as “internal correction”. In Expression 4, the calculation for the correction coefficients being the initial values and the update of the first term in the denominator on the right side correspond to internal correction.

On the other hand, the correction coefficient a₀ updated by Expression 3 is calculated based on the external measurement error Ferror′. Accordingly, the updated correction coefficient a₀ is referred to as an “external correction coefficient”. The correction of a frequency using only the external correction coefficient is referred to as “external correction”. In Expression 4, updating the second term in the denominator on the right side corresponds to external correction.

As described above, the transmission device 200 performs both external and internal corrections. As described in PTL 1, in a configuration in which only the external correction is performed, if the temperature change rate is high, the correction may be required to be more frequently performed. By performing internal correction as well, the frequency is corrected to some extent by the internal correction, so that it is possible to less frequently perform the correction of a frequency than in PTL 1. Furthermore, it is possible to reduce the burden of mounting analog circuits in the transmission/reception system. In addition, it is possible to maintain a stable frequency system that does not depend on frequency fluctuation in mounting and sample variations, which cannot both be corrected by internal correction alone.

### Configuration Example of ADPLL

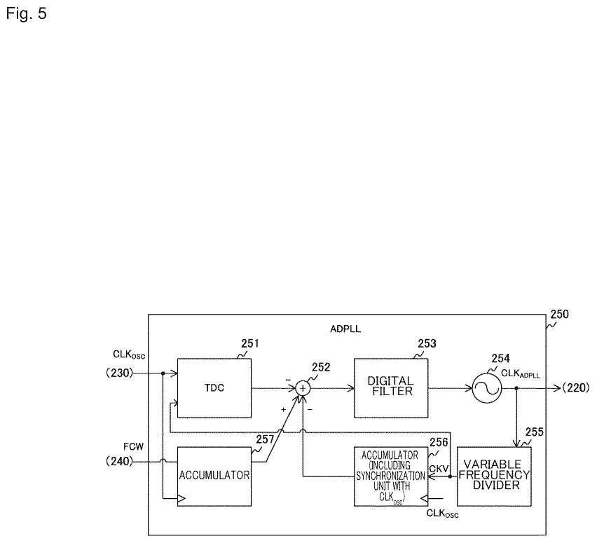

FIG. 5 is a block diagram illustrating a configuration example of the ADPLL 250 according to the first embodiment of the present technology. This ADPLL 250 includes a time-to-digital converter 251, a phase detector 252, a digital filter 253, a digitally-controlled oscillator 254, a variable frequency divider 255, an accumulator (including a synchronization unit with CLK_{OSC}) 256, and an accumulator 257.

The time-to-digital converter 251 converts a phase difference between the master clock signal CLK_{OSC} from the master clock generation unit 230 and a feedback signal CKV from the variable frequency divider 255 into a digital signal. This time-to-digital converter 251 outputs the digital signal to the phase detector 252.

The phase detector 252 subtracts an output value of the time-to-digital converter 251 and an output value of the accumulator 256 from an output value of the accumulator 257. This phase detector 252 supplies a digital control code with high frequency components attenuated to the digitally-controlled oscillator 254 via the digital filter 253.

The digitally-controlled oscillator 254 generates a transmission clock signal CLK_{ADPLL} and controls the frequency of that signal according to the output value of the digital filter 253. The digitally-controlled oscillator 254 outputs the transmission clock signal CLK_{ADPLL} to the data transmission unit 220 and the variable frequency divider 255.

The variable frequency divider 255 divides the frequency of the transmission clock signal CLK_{ADPLL}, and outputs the resulting signal to the accumulator 256 and the TDC 251 as the feedback signal CKV.

The accumulator 256 accumulates (counts) the rising/falling edges output from variable frequency divider 255. The result of accumulation is output to the phase detector 252 in synchronization with the master clock signal CLK_{OSC}.

The accumulator 257 cumulatively adds the frequency control word FCW in synchronization with the master clock signal CLK_{OSC}. This accumulator 257 outputs the result of accumulation of the FCW to the phase detector 252.

The ADPLL 250 is not limited to the configuration illustrated by way of example in the figure as long as it multiplies the master clock signal CLK_{OSC} with the multiplication ratio indicated by the frequency control word FCW.

### Example of Operation of Transmission Device

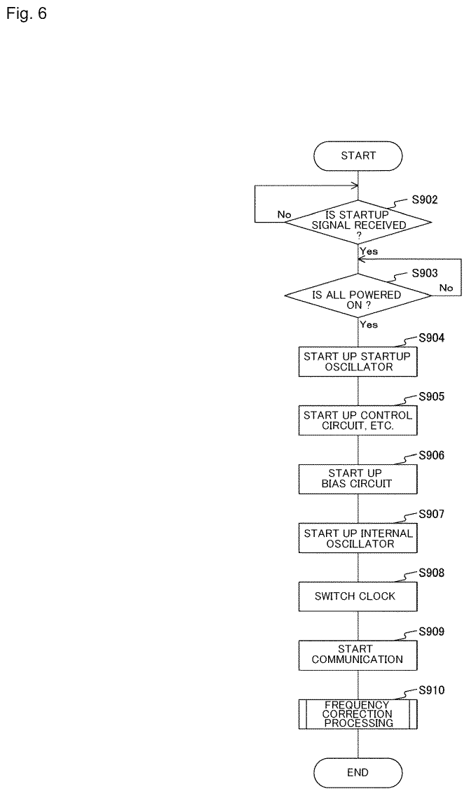

FIG. 6 is a flowchart illustrating an example of an operation of the transmission device 200 according to the first embodiment of the present technology. This operation is started, for example, at a predetermined timing before the start of communication.

The transmission device 200 determines whether or not a startup signal has been received from the reception device 300 (step S902). If a startup signal has not been received (step S902: No), the transmission device 200 repeats step S902.

When a startup signal is received (step S902: Yes), the transmission device 200 determines whether or not all on the transmission side is powered on (step S903). If there is a unit that has not been powered on (step S903: No), the transmission device 200 repeats step S903.

If all is powered on (step S903: Yes), the transmission device 200 starts up the startup oscillator (step S904), and starts up the control circuit 241 and the like (step S905). The transmission device 200 also starts up the bias circuit 218 and the internal oscillator 231 (steps S906 and S907).

Then, the transmission device 200 performs clock switching from CLK_{STRUP} to CLK_{OSC} after a predetermined time has elapsed (step S908).

Subsequently, the transmission device 200 starts communication with the reception device 300 (step S909), and performs frequency correction processing for correcting the frequency of the transmission clock signal CLK_{ADPLL} (step S910). After the frequency correction processing, the transmission device 200 ends the operation for transmission.

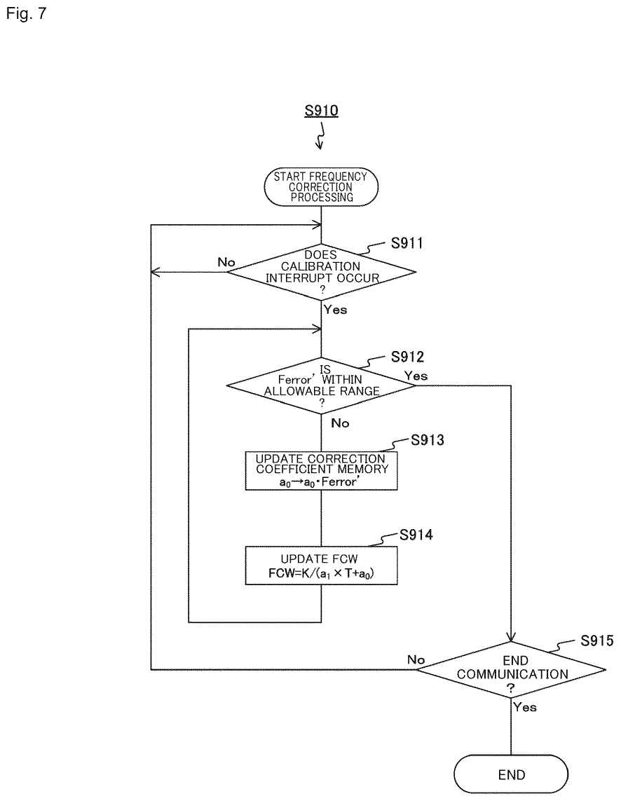

FIG. 7 is a flowchart illustrating an example of the frequency correction processing according to the first embodiment of the present technology. The frequency control unit 240 in the transmission device 200 enables an interrupt for frequency correction, and determines whether or not the interrupt occurs (step S911).

If an interrupt occurs (step S911: Yes), the frequency control unit 240 determines whether or not Expression 2 is satisfied, in other words, whether or not the external measurement error Ferror′ is within the allowable range (step S912). If the external measurement error Ferror′ is within the allowable range (step S912: Yes), the frequency control unit 240 determines whether or not to end the communication.

On the other hand, if the external measurement error Ferror′ is outside the allowable range (step S912: No), the frequency control unit 240 updates the correction coefficient memory 242 using Expression 3 (step S913), and updates the frequency control word FCW using Expression 4 (step S914).

The frequency control unit 240 determines whether communication has ended (step S915). If the communication has not ended (step S915: No) or if no interrupt occurs (step S911: No), the frequency control unit 240 repeats step S911 and subsequent steps. If the communication has ended (step S915: Yes), the frequency control unit 240 ends the frequency correction processing.

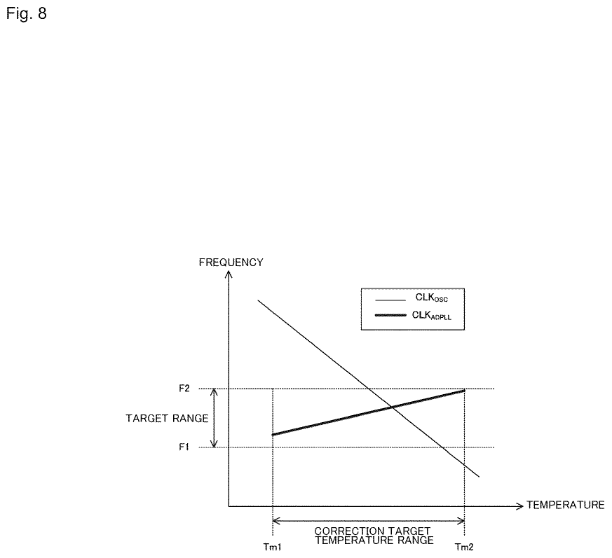

FIG. 8 is a graph illustrating an example of temperature characteristics of the master clock signal CLK_{OSC} and the transmission clock signal CLK_{ADPLL} according to the first embodiment of the present technology. In the figure, the vertical axis indicates the frequency of the clock signal, and the horizontal axis indicates temperature. The thin solid line indicates the temperature characteristic of the master clock signal CLK_{OSC}, and the thick solid line indicates the temperature characteristic of the internally corrected transmission clock signal CLK_{ADPLL}.

As illustrated by way of example in the figure, the master clock signal CLK_{OSC} fluctuates in response to changes in temperature. On the other hand, due to the correction with the internal correction coefficient a₁, the variations in the transmission clock signal CLK_{ADPLL} are significantly smaller than the variations in the master clock signal CLK_{OSC}.

When the correction coefficients a₁ and a₀ accurately match the temperature characteristic of the master clock signal CLK_{OSC}, the transmission clock signal CLK_{ADPLL}, will not change in response to changes in temperature. On the other hand, when the correction coefficients a₁ and a₀ have a slight error from the temperature characteristic of the master clock signal CLK_{OSC}, the transmission clock signal CLK_{ADPLL} will slightly change.

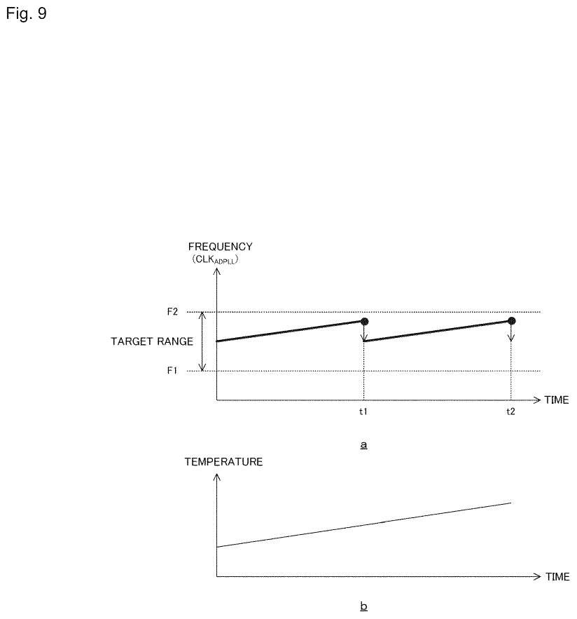

FIG. 9 illustrates an example of frequency fluctuation and temperature fluctuation of the transmission clock signal CLK_{ADPLL}, according to the first embodiment of the present technology. In the figure, a illustrates an example of frequency fluctuation of the transmission clock signal CLK_{ADPLL}, and in the figure, b illustrates an example of temperature fluctuation. In a of the figure, the vertical axis indicates the frequency of the transmission clock signal CLK_{ADPLL}, subjected to the internal and external corrections, and the horizontal axis indicates time. In b of the figure, the vertical axis indicates temperature, and the horizontal axis indicates time.

As illustrated by way of example in b of the figure, it is assumed that the temperature increases with time. In this case, as illustrated by way of example in a in the figure, the frequency of the transmission clock signal CLK_{ADPLL}, increases as the temperature increases. The transmission device 200 performs external correction on the frequency, for example, at timings t1 and t2 so that the frequency does not fall outside a target range. The black circles in the figure indicate the timings of external correction of the frequency.

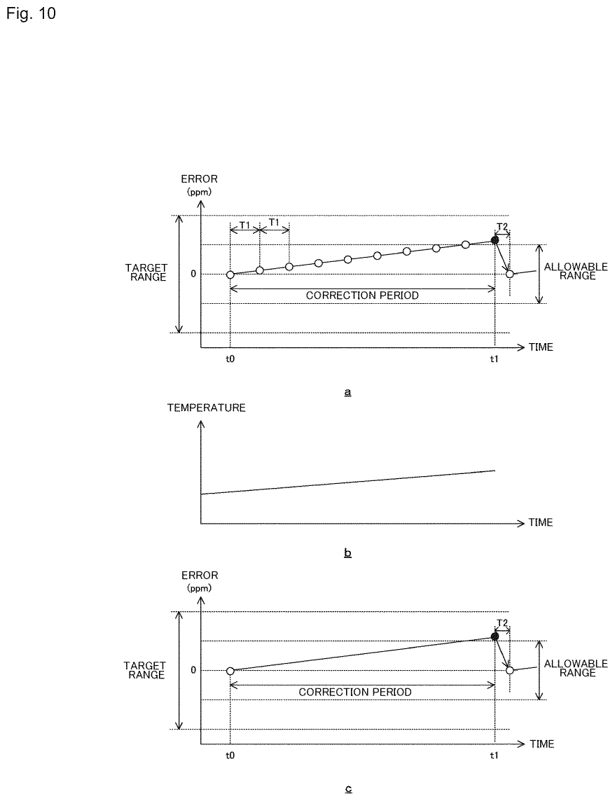

FIG. 10 illustrates an example of error fluctuation and temperature fluctuation according to the first embodiment of the present technology. In the figure, a illustrates an example of frequency error fluctuation of the transmission clock signal CLK_{ADPLL}, and in the figure, b illustrates an example of temperature fluctuation. In a of the figure, the vertical axis indicates the frequency error of the transmission clock signal CLK_{ADPLL} subjected to the internal and external corrections, and the horizontal axis indicates time. In b of the figure, the vertical axis indicates temperature, and the horizontal axis indicates time.

As illustrated by way of example in b of the figure, it is assumed that the temperature increases with time. In this case, as illustrated by way of example in a of the figure, the frequency of the transmission clock signal CLK_{ADPLL}, fluctuates as the temperature changes, causing an error. For example, the error increases in the positive direction as the temperature increases.

The transmission device 200 receives the external measurement error ΔFₑᵣᵣₒᵣ every time a period T1 elapses from a predetermined timing to with no error. The circle marks in a of the figure indicate timings of receiving the external measurement error. The transmission device 200 determines whether or not the external measurement error Ferror′ is within the allowable range using Expression 2. The white circle marks in a of the figure indicate that an external measurement error is received while correction is not performed because the external measurement error Ferror′ is within the allowable range.

Then, if the external measurement error Ferror′ is outside the allowable range, the transmission device 200 updates the correction coefficient a₀ using Expression 3, updates the frequency control word FCW using Expression 4, and corrects the frequency using the frequency control word FCW. Let T2 be the time required for this processing. The allowable range is set with a certain margin so as not to exceed the target range of error. The black circle in a of the figure indicates a timing t1 of correcting the frequency. The difference between t0 and t1 is defined as a correction period. As illustrated by way of example in c of the figure, if the reception device 300 performs control to transmit only when the external measurement error ΔFerror is larger than a certain threshold value, the frequency of transmission of the measurement error ΔFerror in the reception device 300 can be reduced.

A transmission/reception system that performs only the external correction as in PTL 1 is now given as a comparative example. In the comparative example, it is assumed that a transmission clock signal is generated by an oscillator such as a voltage-controlled oscillator without using the ADPLL 250.

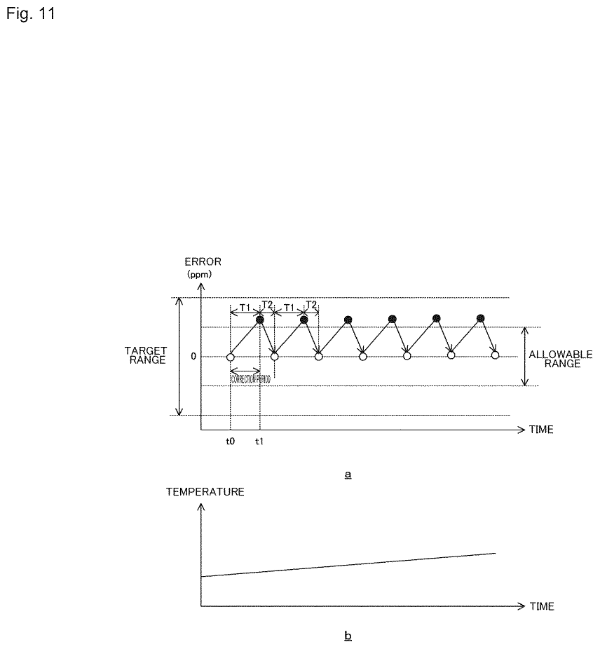

FIG. 11 illustrates an example of error fluctuation and temperature fluctuation in the comparative example. The error fluctuation (inclination) with respect to temperature is larger than that in FIG. 10 because the internal correction is not performed. The transmission device of the comparative example performs processing of correcting the error based on the set value every time a period T1 elapses from a predetermined timing to with no error. The time required for this processing is referred to as T2. The black circles in the figure indicate timings of correcting the frequency. Let t1 be the time from the predetermined timing to with no particular error to the first timing of correcting the frequency. When the difference between t0 and t1 is defined as a correction period, the correction period in a of FIG. 10a is longer than the correction period in a of FIG. 11a. In other words, the correction can less frequently be performed.

As described above, in the comparative example in which only the external correction is performed, the accuracy of correction is reduced, so that the correction of the frequency to fall within the target range will more frequently be performed. By contrast, in the transmission device 200 that further performs the internal correction in addition to the external correction, the accuracy of correction is improved compared to the case where only the external correction is performed, so that the correction can less frequently be performed.

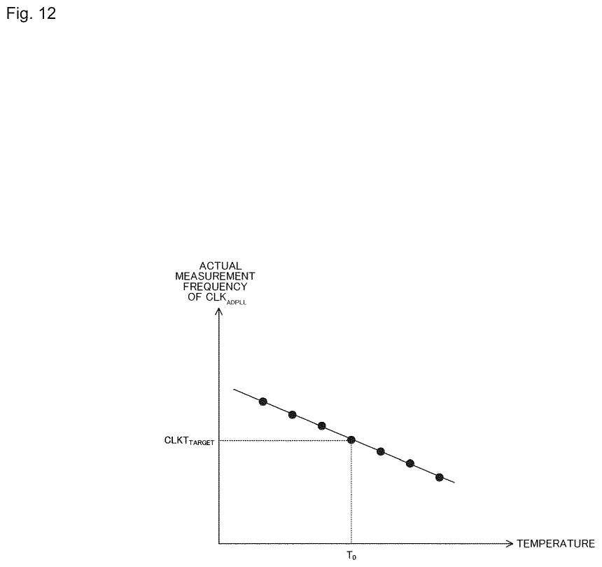

FIG. 12 illustrates a method for determining initial values for correction coefficients according to the first embodiment of the present technology. In the figure, the vertical axis indicates the actually measured frequency of the transmission clock signal CLK_{ADPLL}, and the horizontal axis indicates temperature. A value obtained by dividing the frequency of the transmission clock signal CLK_{ADPLL} on the vertical axis by the frequency of the master clock signal CLK_{OSC} corresponds to the multiplication ratio (FCW). For example, the following relational expression is established between this FCW and temperature.

$$FCW = K / \{ {b}_{1} ( T - {T}_{0} ) + {b}_{0} \} \qquad Expression 5$$

The transmission device 200 actually measures the frequency of the transmission clock signal CLK_{ADPLL} under a plurality of temperature conditions to acquire sample values, calculates the correction coefficients b₁ and b₀ in Expression 5, and holds them as initial values in the correction coefficient memory 242. The black circles in FIG. 12 indicate sample values. To acquire the sample values, the transmission device 200 may be provided with a reference clock supply path from the outside of the transmission device 200 and a frequency counter (both not illustrated).

Expression 5 is another representation of Expression 4. This indicates that the frequency of the master clock signal CLK_{OSC} at a certain temperature T₀ is b₀. Let CLK_{OSC} (T) and CLK_{ADPLL}. (T) be the temperature, the temperature characteristics of the frequency of the master clock signal CLK_{OSC} and the frequency of the transmission clock signal CLK_{ADPLL}, respectively, and let CLK_{TARGET} be a reference frequency of the transmission clock signal. For example, b₀ may be calculated to satisfy Expression 6.

$$C L {K}_{T A R G E T} ≡ C L {K}_{A D P L L} ( {T}_{0} ) = {CLK}_{OSC} ( {T}_{0} ) K / {b}_{0} \qquad Expression 6$$

In Expression 5, the order of temperature is set to 1, but it can also be set to 2 or more. In this case, for example, the following expression is used instead of Expression 5.

$$FCW = K / \{ {{b}_{3} ( T - {T}_{0} )}^{3} + {{b}_{2} ( T - {T}_{0} )}^{2} + {b}_{1} ( T - {T}_{0} ) + {b}_{0} \} \qquad Expression 7$$

In a case where the sense circuit 213 measures the power supply voltage VDD in addition to the temperature T, the following expression is used instead of Expression 5, for example.

$$FCW = K / \{ {b}_{1} ( T - {T}_{0} ) + {b}_{0} + f ( V DD , VP , IP ) \} \qquad Expression 8$$

In the above expression, f (VDD) is a function of the power supply voltage VDD, a voltage VP indicating process information, or a current IP. The order of the temperature in Expression 8 can also be set to 2 or more. In a case where the sense circuit 213 measures only the power supply voltage VDD, a function of the power supply voltage VDD is used instead of Expression 5.

$$FCW = L / f ( {b}_{3} , {b}_{2} , {b}_{1} , {b}_{0} , {T}_{0} , T , VDD , VP , IP ) \qquad Expression 9$$

Although the denominator of Expression 8 is calculated as the sum of a function related to temperature and a function related to power supply and process, any calculation may be applied like the denominator of Expression 9.

As described above, according to the first embodiment of the present technology, since the transmission device controls the frequency of the transmission clock signal based on the external measurement error and the measurement values (temperature, etc.) measured on the transmission side, the correction can less frequently be performed compared to the case where only the external correction is performed.

### 2. Second Embodiment

In the first embodiment described above, the transmission device 200 transmits clock signals using the clock-embedded method, but this configuration requires the clock data recovery circuit 312 on the reception side. A transmission/reception system in a second embodiment differs from the first embodiment in that clock signals are transmitted using the source synchronous method.

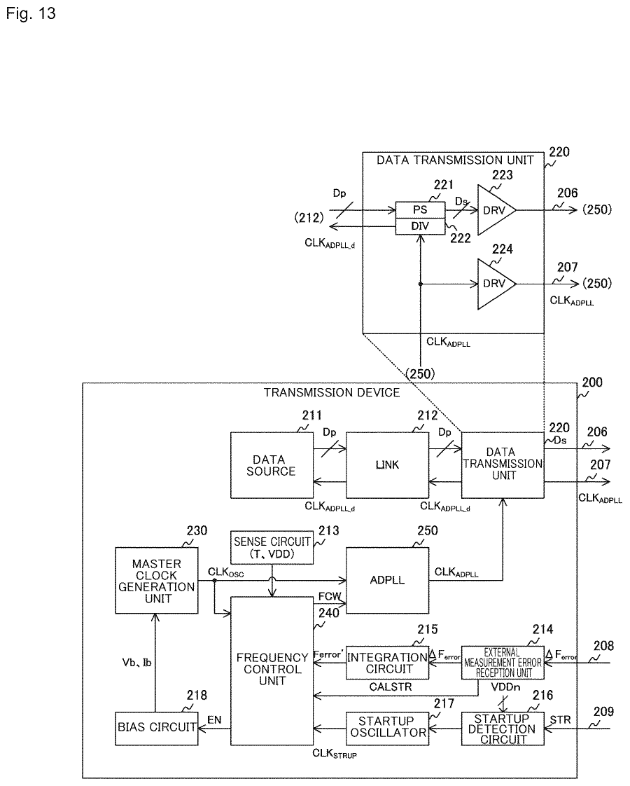

FIG. 13 is a block diagram illustrating a configuration example of a transmission device 200 according to the second embodiment of the present technology. This transmission device 200 of the second embodiment differs from the first embodiment in that it further includes a driver 224 within the data transmission unit 220.

The driver 223 of the first embodiment transmits data Ds. The driver 224 transmits a transmission clock signal CLK_{ADPLL} via the signal line 207. The drivers 223 and 224 are examples of first and second drivers described in the claims.

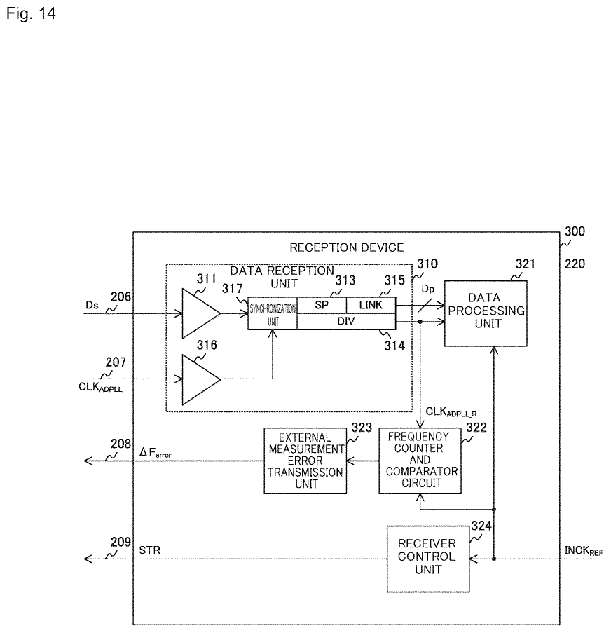

FIG. 14 is a block diagram illustrating a configuration example of a reception device 300 according to the second embodiment of the present technology. The reception device 300 of the second embodiment includes a driver 316 and a synchronization unit 317 instead of the clock data recovery circuit 312.

The driver 311 of the second embodiment receives the data Ds and supplies it to the synchronization unit 317. The driver 316 receives the transmission clock signal CLK_{ADPLL} and supplies it to the synchronization unit 317. The drivers 311 and 316 are examples of third and fourth drivers described in the claims.

The synchronization unit 317 captures the data Ds in synchronization with the transmission clock signal CLK_{ADPLL}, and supplies it to the serial-to-parallel converter 313.

As illustrated by way of example in the figure, transmitting and receiving clock signals using the source synchronous method makes the clock data recovery circuit 312 unnecessary.

As described above, according to the second embodiment of the present technology, since the transmission device 200 transmits the clock signals using the source synchronous method, the clock data recovery circuit 312 can be eliminated.

### Example of Application to Imaging Device

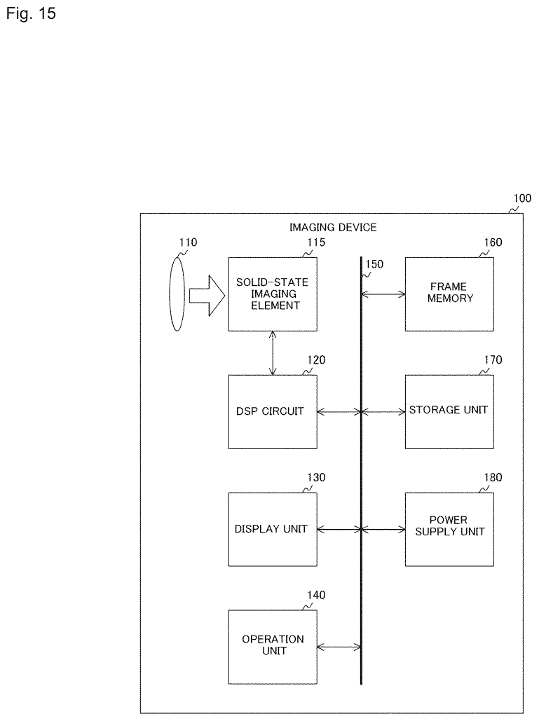

FIG. 15 is a block diagram illustrating a configuration example of an imaging device 100 according to an embodiment of the present technology. The transmission/reception systems of the first and second embodiments can be applied to the imaging device 100.

The imaging device 100 is a device for capturing image data, and includes an optical unit 110, a solid-state imaging element 115, and a digital signal processing (DSP) circuit 120. The imaging device 100 further includes a display unit 130, an operation unit 140, a bus 150, a frame memory 160, a storage unit 170, and a power supply unit 180. As the imaging device 100, for example, a smartphone, a personal computer, an in-vehicle camera, or the like having an imaging function is conceivable in addition to a digital camera such as a digital still camera.

The optical unit 110 focuses light from a subject and guides the light to the solid-state imaging element 115. The solid-state imaging element 115 generates image data through photoelectric conversion in synchronization with a vertical synchronization signal VSYNC. The vertical synchronization signal VSYNC is a periodic signal having a predetermined frequency indicating an imaging timing. The solid-state imaging element 115 supplies the generated image data to the DSP circuit 120.

The DSP circuit 120 executes predetermined signal processing on the image data from the solid-state imaging element 115. This DSP circuit 120 outputs the processed image data to the frame memory 160 and the like via the bus 150.

The display unit 130 displays the image data. As the display unit 130, for example, a liquid crystal panel or an organic electro luminescence (EL) panel may be conceived. The operation unit 140 generates an operation signal according to an operation of a user.

The bus 150 is a common path through which the optical unit 110, the solid-state imaging element 115, the DSP circuit 120, the display unit 130, the operation unit 140, the frame memory 160, the storage unit 170, and the power supply unit 180 exchange data with each other.

The frame memory 160 holds the image data. The storage unit 170 stores various types of data, such as the image data. The power supply unit 180 supplies power to the solid-state imaging element 115, the DSP circuit 120, the display unit 130, and the like.

For example, the first and second embodiments can be applied to an interface between the solid-state imaging element 115 and the DSP circuit 120 in the figure. In this case, the solid-state imaging element 115 is used as the transmission device 200, and the DSP circuit 120 is used as the reception device 300.

### 3. Example of Application to Moving Body

The technology according to the present disclosure (the present technology) can be applied to various products. For example, the technology according to the present disclosure may be implemented as a device equipped in any type of moving body such as an automobile, an electric vehicle, a hybrid electric vehicle, a motorcycle, a bicycle, a personal mobility device, an airplane, a drone, a ship, and a robot.

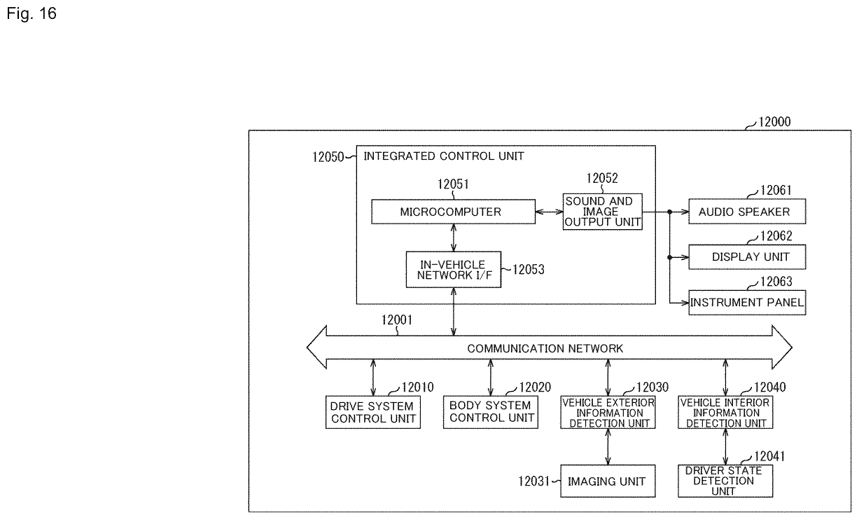

FIG. 16 is a block diagram illustrating a schematic configuration example of a vehicle control system, which is an example of a moving body control system to which the technology according to the present disclosure can be applied.

The vehicle control system 12000 includes a plurality of electronic control units connected thereto via a communication network 12001. In the example illustrated in FIG. 16, the vehicle control system 12000 includes a drive system control unit 12010, a body system control unit 12020, a vehicle exterior information detection unit 12030, a vehicle interior information detection unit 12040, and an integrated control unit 12050. In addition, as a functional configuration of the integrated control unit 12050, a microcomputer 12051, a sound and image output unit 12052, and an in-vehicle network interface (I/F) 12053 are illustrated.

The drive system control unit 12010 controls operations of devices related to a drive system of a vehicle in accordance with various programs. For example, the drive system control unit 12010 functions as a control device for a driving force generation device for generating the driving force of the vehicle such as an internal combustion engine or a drive motor, a driving force transmission mechanism for transmitting the driving force to the wheels, a steering mechanism for adjusting the steering angle of the vehicle, a braking device for generating the braking force of the vehicle, or the like.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle exterior information detection unit 12030 detects information on the outside of the vehicle equipped with the vehicle control system 12000. For example, an imaging unit 12031 is connected to the vehicle exterior information detection unit 12030. The vehicle exterior information detection unit 12030 causes the imaging unit 12031 to capture an image of the outside of the vehicle and receives the captured image. The vehicle exterior information detection unit 12030 may perform object detection processing or distance detection processing for people, cars, obstacles, signs, and letters on the road on the basis of the received image.

The imaging unit 12031 is an optical sensor that receives light and outputs an electrical signal according to the amount of received light. The imaging unit 12031 can also output the electrical signal as an image or distance measurement information. In addition, the light received by the imaging unit 12031 may be visible light or invisible light such as infrared light.

The vehicle interior information detection unit 12040 detects information on the inside of the vehicle. For example, a driver state detection unit 12041 that detects a driver's state is connected to the vehicle interior information detection unit 12040. The driver state detection unit 12041 includes, for example, a camera that captures an image of a driver, and the vehicle interior information detection unit 12040 may calculate a degree of fatigue or concentration of the driver or may determine whether or not the driver is dozing on the basis of detection information input from the driver state detection unit 12041.

The microcomputer 12051 can calculate control target values for the driving force generation device, the steering mechanism, or the braking device on the basis of information on the inside and outside of the vehicle, the information being acquired by the vehicle exterior information detection unit 12030 or the vehicle interior information detection unit 12040, and the microcomputer 12051 can output control commands to the drive system control unit 12010. For example, the microcomputer 12051 can perform cooperative control for the purpose of implementing the functions of an advanced driver assistance system (ADAS) including vehicle collision avoidance, impact mitigation, following traveling based on an inter-vehicle distance, vehicle speed maintenance driving, vehicle collision warning, and vehicle lane deviation warning.

Further, by controlling the driving force generation device, the steering mechanism, the braking device, and the like on the basis of information regarding the vicinity of the vehicle acquired by the vehicle exterior information detection unit 12030 or the vehicle interior information detection unit 12040, the microcomputer 12051 can perform cooperative control for the purpose of automated driving or the like in which autonomous travel is performed without depending on an operation of the driver.

The microcomputer 12051 can also output a control command to the body system control unit 12020 based on the information outside the vehicle acquired by the vehicle exterior information detection unit 12030. For example, the microcomputer 12051 can perform cooperative control for the purpose of preventing glare such as controlling the headlamps to switch a high beam to a low beam according to the position of a preceding vehicle or an oncoming vehicle detected by the vehicle exterior information detection unit 12030.

The sound and image output unit 12052 transmits an output signal of at least one of sound and an image to an output device capable of visually or audibly notifying a passenger or the outside of the vehicle of information. In the example of FIG. 16, an audio speaker 12061, a display unit 12062, and an instrument panel 12063 are illustrated as the output device. The display unit 12062 may include, for example, at least one of an on-board display and a heads-up display.

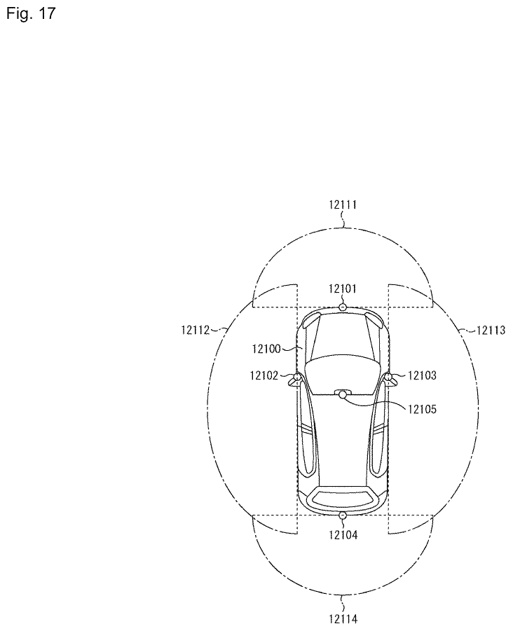

FIG. 17 illustrates an example of installation positions of imaging units 12031.

In FIG. 17, imaging units 12101, 12102, 12103, 12104, and 12105 are provided as the imaging units 12031.

The imaging units 12101, 12102, 12103, 12104, and 12105 are provided at positions such as a front nose, side view mirrors, a rear bumper, a back door, and an upper portion of a windshield in a vehicle interior of a vehicle 12100, for example. The imaging unit 12101 provided on the front nose and the imaging unit 12105 provided in the upper portion of the windshield in the vehicle interior mainly acquire images of a side in front of the vehicle 12100. The imaging units 12102 and 12103 provided on the side-view mirrors mainly acquire images of lateral sides from the vehicle 12100. The imaging unit 12104 provided on the rear bumper or the back door mainly captures images behind the vehicle 12100. The imaging unit 12105 provided in the upper portion of the windshield in the vehicle is mainly used for detecting, for example, vehicles ahead, pedestrians, obstacles, traffic signals, traffic signs, or lanes.

FIG. 17 illustrates an example of imaging ranges of the imaging units 12101 to 12104. An imaging range 12111 indicates an imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, by superimposing image data captured by the imaging units 12101 to 12104, it is possible to obtain a bird's-eye view image viewed from the upper side of the vehicle 12100.

At least one of the imaging units 12101 to 12104 may have a function for obtaining distance information. For example, at least one of the imaging units 12101 to 12104 may be a stereo camera constituted by a plurality of imaging elements or may be an imaging element that has pixels for phase difference detection.

For example, the microcomputer 12051 can extract, particularly, a closest three-dimensional object on a path along which the vehicle 12100 is traveling, which is a three-dimensional object traveling at a predetermined speed (e.g., 0 km/h or higher) in the substantially same direction as the vehicle 12100, as a vehicle ahead by acquiring a distance to each three-dimensional object in the imaging ranges 12111 to 12114 and a temporal change of the distance (a relative speed with respect to the vehicle 12100) on the basis of the distance information obtained from the imaging units 12101 to 12104. Furthermore, the microcomputer 12051 can set an inter-vehicle distance to be secured from a vehicle ahead in advance with respect to the vehicle ahead and can perform automated brake control (also including following stop control) or automated acceleration control (also including following start control). In this way, cooperative control can be performed for the purpose of automated driving or the like in which a vehicle autonomously travels without depending on the operations of the driver.

For example, the microcomputer 12051 can classify and extract three-dimensional data regarding three-dimensional objects into other three-dimensional objects such as a two-wheeled vehicle, an ordinary vehicle, a large-size vehicle, a pedestrian, and an electric pole on the basis of distance information obtained from the imaging units 12101 to 12104 and can use the other three-dimensional objects to perform automated avoidance of obstacles. For example, the microcomputer 12051 differentiates surrounding obstacles of the vehicle 12100 into obstacles which can be viewed by the driver of the vehicle 12100 and obstacles which are difficult to view. Then, the microcomputer 12051 determines a collision risk indicating the degree of risk of collision with each obstacle, and when the collision risk is equal to or greater than a set value and there is a possibility of collision, an alarm is output to the driver through the audio speaker 12061 or the display unit 12062, forced deceleration or avoidance steering is performed through the drive system control unit 12010, and thus it is possible to perform driving support for collision avoidance.

At least one of the imaging units 12101 to 12104 may be an infrared camera that detects infrared light. For example, the microcomputer 12051 can recognize a pedestrian by determining whether or not a pedestrian is present in captured images of the imaging units 12101 to 12104. Such pedestrian recognition is performed, for example, through a step of extracting feature points in the images captured by the imaging units 12101 to 12104 as infrared cameras and a step of performing pattern matching processing on a series of feature points indicating an outline of an object to determine whether or not the object is a pedestrian. When the microcomputer 12051 determines that pedestrians are in the images captured by the imaging units 12101 to 12104 and recognizes the pedestrians, the sound and image output unit 12052 controls the display unit 12062 such that rectangular contour lines for emphasis are superimposed and displayed on the recognized pedestrians. In addition, the sound and image output unit 12052 may control the display unit 12062 such that icons and the like indicating pedestrians are displayed at desired positions.

An example of the vehicle control system to which the technology according to the present disclosure can be applied has been described above. The technology of the present disclosure can be applied to the imaging unit 12031 in the above-described configurations. Specifically, the transmission/reception system of FIG. 1 can be applied to an interface within the imaging unit 12031. By applying the technology according to the present disclosure to the imaging unit 12031, the correction of the frequency can less frequently be performed, so that it is possible to improve the stability of communication.

### 4. Example of Application to In-Body Information Acquisition System

The technology according to the present disclosure can be applied to various products. For example, the technology according to the present disclosure may be applied to an in-body information acquisition system for patients using a capsule endoscope.

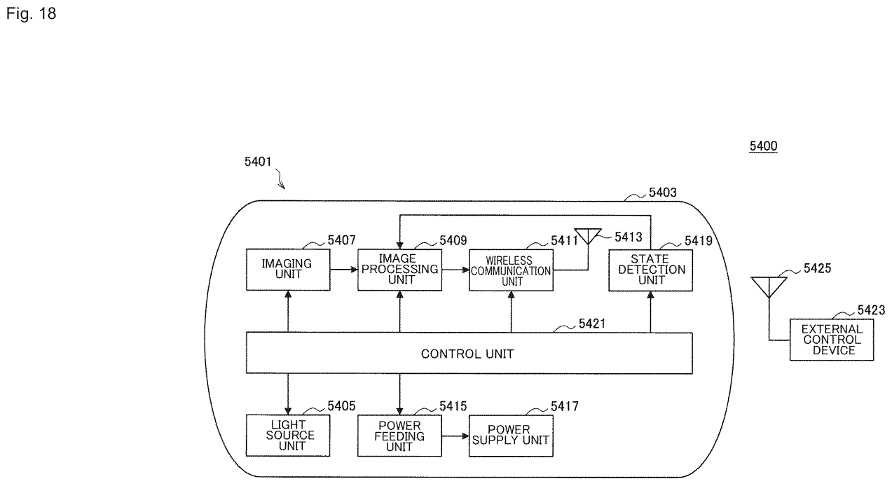

FIG. 18 is a diagram illustrating an example of a schematic configuration of an in-body information acquisition system 5400 to which the technology according to the present disclosure can be applied. Referring to FIG. 18, the in-body information acquisition system 5400 includes a capsule endoscope 5401 and an external control device 5423 that centrally controls the operation of the in-body information acquisition system 5400. For an examination, the capsule endoscope 5401 is swallowed by a patient. The capsule endoscope 5401 has an imaging function and a wireless communication function, and sequentially captures images of organs such as the stomach and intestines (hereinafter also referred to as in-body images) at predetermined intervals and sequentially wirelessly transmits information about the in-body images to an external control device 5423 outside the body while moving inside the organs by their peristalsis and the like until it is naturally excreted from the patient. The external control device 5423 generates image data to display the in-body images on a display device (not illustrated) based on the received information about the in-body images. In the in-body information acquisition system 5400, in this way, it is possible to obtain in-body images of the inside of the patient at any time from the time when the capsule endoscope 5401 is swallowed until it is excreted.

Configurations and functions of the capsule endoscope 5401 and the external control device 5423 will be described in more detail. As illustrated in the figure, the capsule endoscope 5401 is configured to have, in a capsule type casing 5403, functions of a light source unit 5405, an imaging unit 5407, an image processing unit 5409, a wireless communication unit 5411, a power feeding unit 5415, a power supply unit 5417, a state detection unit 5419, and a control unit 5421.

The light source unit 5405 includes, for example, a light source such as a light emitting diode (LED), and irradiates an imaging visual field of the imaging unit 5407 with light.

The imaging unit 5407 includes an optical system including an imaging element and a plurality of lenses provided in front of the imaging element. Reflected light (hereinafter referred to as observation light) of the light with which a body tissue as an observation target is irradiated is collected by the optical system, and enters the imaging element. The imaging element receives the observation light and performs photoelectric conversion to generate an electric signal corresponding to the observation light, that is, an image signal corresponding to an observation image. The image signal generated by the imaging unit 5407 is provided to the image processing unit 5409. As the imaging element of the imaging unit 5407, various known image sensors may be used such as a complementary metal oxide semiconductor (CMOS) image sensor or a charge coupled device (CCD) image sensor.

The image processing unit 5409 is configured by a processor such as a central processing unit (CPU) or a graphics processing unit (GPU), and performs various types of signal processing on the image signal generated by the imaging unit 5407. That signal processing may be minimum processing (e.g., image data compression, frame rate conversion, data rate conversion, and/or format conversion) to transmit the image signal to the external control device 5423. The image processing unit 5409 being configured to perform only the minimum necessary processing results in the image processing unit 5409 in a smaller size and with lower power consumption, which is suitable for the capsule endoscope 5401. However, if there is sufficient space within the casing 5403 and power consumption, the image processing unit 5409 may perform further signal processing (e.g., noise removal processing or other image quality enhancement processing). The image processing unit 5409 provides the image signal subjected to the signal processing to the wireless communication unit 5411 as RAW data. If the state detection unit 5419 has acquired information on the state (movement, posture, etc.) of the capsule endoscope 5401, the image processing unit 5409 may link the image signal with that information and provide the resulting image signal to the wireless communication unit 5411. This makes it possible to associate the captured image with the position in the body where the image was captured, the direction in which the image was captured, and the like.

The wireless communication unit 5411 is configured by a communication device for transmitting and receiving various types of information to and from the external control device 5423. The communication device includes an antenna 5413, a processing circuit that performs modulation processing and the like for transmitting and receiving signals, and the like. The wireless communication unit 5411 performs predetermined processing such as modulation processing on the image signal subjected to the signal processing by the image processing unit 5409, and transmits the resulting image signal to the external control device 5423 via the antenna 5413. The wireless communication unit 5411 also receives a control signal regarding drive control of the capsule endoscope 5401 from the external control device 5423 via the antenna 5413. The communication unit 5411 provides the received control signal to the control unit 5421.

The power feeding unit 5415 includes an antenna coil for power reception, a power regeneration circuit that regenerates electric power from the current generated in the antenna coil, a booster circuit, and the like. The power feeding unit 5415 generates electric power using the principle of so-called non-contact charging. Specifically, by externally applying a magnetic field (electromagnetic wave) with a predetermined frequency to the antenna coil of the power feeding unit 5415, an induced electromotive force is generated in the antenna coil. The electromagnetic wave may be a carrier wave transmitted from the external control device 5423 via an antenna 5425, for example. Electric power is regenerated from the induced electromotive force by a power regeneration circuit, and the potential thereof is adjusted in the booster circuit as appropriate, thereby generating electric power for storage. The electric power generated by the power feeding unit 5415 is stored in the power supply unit 5417.

The power supply unit 5417 is configured by a secondary battery and stores electric power generated by the power feeding unit 5415. Although arrows indicating power supply destinations from the power supply unit 5417 and the like are not illustrated in FIG. 18 in order to avoid making the drawings complicated, the electric power stored in the power supply unit 5417 can be supplied to the light source unit 5405, the imaging unit 5407, the image processing unit 5409, the wireless communication unit 5411, the state detection unit 5419, and the control unit 5421 and be used to drive these.

The state detection unit 5419 includes sensors for detecting the state of the capsule endoscope 5401, such as an acceleration sensor and/or a gyro sensor. The state detection unit 5419 can acquire information on the state of the capsule endoscope 5401 from detection results by the sensors. The state detection unit 5419 provides the acquired information on the state of the capsule endoscope 5401 to the image processing unit 5409. As described above, the image processing unit 5409 can link the information on the state of the capsule endoscope 5401 with the image signal.

The control unit 5421 is configured by a processor such as a CPU, and centrally controls the operation of the capsule endoscope 5401 by operating according to a predetermined program. The control unit 5421 controls as appropriate the driving of the light source unit 5405, the imaging unit 5407, the image processing unit 5409, the wireless communication unit 5411, the power feeding unit 5415, the power supply unit 5417, and the state detection unit 5419 in accordance with the control signal transmitted from the external control device 5423, thereby implementing the functions of the units as described above.

The external control device 5423 may be a processor such as a CPU or a GPU, or a microcomputer or control board on which a processor and a storage element such as a memory are mounted together. The external control device 5423 includes the antenna 5425 and is configured to be able to transmit and receive various types of information to and from the capsule endoscope 5401 via the antenna 5425. Specifically, the external control device 5423 controls the operation of the capsule endoscope 5401 by transmitting a control signal to the control unit 5421 of the capsule endoscope 5401. For example, by the control signal from the external control device 5423, the light irradiation conditions for the observation target in the light source unit 5405 can be changed. Also, by the control signal from the external control device 5423, the imaging conditions (e.g., the frame rate, the exposure value, etc. in the imaging unit 5407) can be changed. By the control signal from the external control device 5423, the content of processing in the image processing unit 5409 and the conditions for the wireless communication unit 5411 to transmit image signals (e.g., the transmission interval, the number of transmitted images, etc.) may be changed.

The external control device 5423 performs various types of image processing on the image signal transmitted from the capsule endoscope 5401, and generates image data to display the captured in-body images on the display device. Examples of the types of image processing to be performed include various known types of signal processing such as development processing (demosaic processing), high image quality processing (band emphasis processing, super resolution processing, noise reduction (NR) processing and/or camera shake correction processing, etc.), and/or enlargement processing (electronic zoom processing). The external control device 5423 controls the driving of the display device (not illustrated) to display the in-body images captured based on the generated image data. Alternatively, the external control device 5423 may cause a recording device (not illustrated) to record the generated image data or cause a printing device (not illustrated) to print out the generated image data.

The example of the in-body information acquisition system 5400 to which the technique according to the present disclosure can be applied has been described above. The technology according to the present disclosure can be applied to the imaging unit 10112 and the image processing unit 10113 in the configuration described above. Specifically, the transmission device 200 of FIG. 1 can be applied to the imaging unit 10112. The reception device 300 of FIG. 2 can be applied to the image processing unit 10113. By applying the technology according to the present disclosure to the imaging unit 10112 and the image processing unit 10113, the correction of the frequency can less frequently be performed, so that it is possible to improve the stability of communication. Although a capsule endoscope has been described as an example of application to an in-body information acquisition system, the technology according to the present disclosure can be applied to an interface between an imaging unit in a wired endoscope and an external device.

The above-described embodiments show examples for embodying the present technology, and matters in the embodiments and matters specifying the invention in the claims have a corresponding relationship with each other. Similarly, the matters specifying the invention in the claims and the matters having the same names in the embodiments of the present technology are correlated with each other. However, the present technology is not limited to the embodiments and can be embodied by applying various modifications to the embodiments without departing from the scope and spirit thereof.

The effects described in the present specification are merely examples and are not intended as limiting, and other effects may be obtained.

The present technique can also be configured as follows.

(1) A transmission device including:
a transmission clock signal generation unit that generates a transmission clock signal;
a transmission unit that transmits the transmission clock signal;
an error acquisition unit that acquires an external measurement error that is an error in a frequency of a reception clock signal measured by a reception device that receives the transmission clock signal and generates the reception clock signal from the transmission clock signal; and
a frequency control unit that controls a frequency of the transmission clock signal based on the external measurement error and a measurement value measured on a transmission side.

(2) The transmission device according to (1), wherein the transmission unit includes a driver that embeds the transmission clock signal in data and transmits the data.

(3) The transmission device according to (1), wherein the transmission unit includes
a first driver that transmits data, and
a second driver that transmits the transmission clock signal.

(4) The transmission device according to any one of (1) to (3), wherein
the transmission clock signal generation unit is an all digital phase-locked loop (ADPLL) that multiplies a master clock signal, and
the frequency control unit includes
a correction coefficient holding unit that holds a predetermined number of correction coefficients,
a frequency control word generation unit that generates, based on the measurement value and the held correction coefficients, a frequency control word indicating a multiplication ratio of the ADPLL, and
a control circuit that updates the held correction coefficients based on the external measurement error.

(5) The transmission device according to (4), wherein the measurement value includes at least one of a temperature, a power supply voltage, and a voltage or current value that indicates process information.

(6) The transmission device according to (4) or (5), wherein
the measurement value includes an actual measurement frequency of the transmission clock signal measured on the transmission side, and
the control circuit sets initial values for the correction coefficients based on the actual measurement frequency.

(7) The transmission device according to any one of (4) to (6), wherein
the control circuit updates the held correction coefficients when the external measurement error is outside a predetermined range, and
the frequency control word generation unit updates the frequency control word when the correction coefficients are updated.

(8) The transmission device according to any one of (1) to (7), further including a startup oscillator that generates a predetermined startup clock signal when a startup signal from the reception device is detected,
wherein the frequency control unit controls the frequency in synchronization with the startup clock signal.

(9) A transmission/reception system including:
a reception device that receives a transmission clock signal, generates a reception clock signal from the transmission clock signal, and measures an error in a frequency of the reception clock signal as an external measurement error; and
a transmission device that includes an error acquisition unit that acquires the external measurement error, a clock signal generation unit that generates a transmission clock signal, a transmission unit that transmits the transmission clock signal, and a frequency control unit that controls a frequency of the transmission clock signal based on the external measurement error and a measurement value measured on a transmission side.

(10) The transmission/reception system according to (9), wherein
the transmission unit includes a first driver that embeds the transmission clock signal in data and transmits the data, and
the reception device includes
a third driver that receives the data, and
a clock data recovery circuit that extracts the transmission clock signal from the received data.

(11) The transmission/reception system according to (9), wherein
the transmission unit includes
a first driver that transmits data, and
a second driver that transmits the transmission clock signal,
wherein
the reception device includes
a third driver that receives the data, and
a fourth driver that receives the transmission clock signal.

(12) A method for controlling a transmission device, including:
a clock signal generation step of generating a transmission clock signal;
a transmission step of transmitting the transmission clock signal;
an error acquisition step of acquiring an external measurement error that is an error in a frequency of a reception clock signal measured by a reception device that receives the transmission clock signal and generates the reception clock signal from the transmission clock signal; and
a frequency control step of controlling a frequency of the transmission clock signal based on the external measurement error and a measurement value measured on a transmission side.

### REFERENCE SIGNS LIST

100 Imaging device
110 Optical unit
115 Solid-state imaging element
120 DSP circuit
130 Display unit
140 Operation unit
150 Bus
160 Frame memory
170 Storage unit
180 Power supply unit
200 Transmission device
211 Data source
212 Link unit
213 Sense circuit
214 External measurement error reception unit
215 Integration circuit
216 Startup detection circuit
217 Startup oscillator
218 Bias circuit
220 Data transmission unit
221 Parallel-to-serial converter
222, 232, 314 Frequency divider
223, 224 Driver
230 Master clock generation unit
231 Internal oscillator
240 Frequency control unit
241 Control circuit
242 Correction coefficient memory
243 AD converter
244 Frequency control word generation unit
250 ADPLL
251 Time-to-digital converter
252 Phase detector
253 Digital filter
254 Digitally-controlled oscillator
255 Variable frequency divider
256 Accumulator (including synchronization unit with CLK_{OSC})
257 Accumulator
300 Reception device
310 Data reception unit
311, 316 Driver
312 Clock data recovery circuit
313 Parallel-to-serial converter
315 Link unit
317 Synchronization unit
321 Data processing unit
322 Frequency counter and comparator circuit
323 External measurement error transmission unit
324 Receiver control unit
12031 Imaging unit

1. A transmission device comprising:
a transmission clock signal generation unit that generates a transmission clock signal;
a transmission unit that transmits the transmission clock signal;
an error acquisition unit that acquires an external measurement error that is an error in a frequency of a reception clock signal measured by a reception device that receives the transmission clock signal and generates the reception clock signal from the transmission clock signal; and
a frequency control unit that controls a frequency of the transmission clock signal based on the external measurement error and a measurement value measured on a transmission side.

2. The transmission device according to claim 1, wherein the transmission unit includes a driver that embeds the transmission clock signal in data and transmits the data.

3. The transmission device according to claim 1, wherein
the transmission unit includes
a first driver that transmits data, and
a second driver that transmits the transmission clock signal.

4. The transmission device according to claim 1, wherein
the transmission clock signal generation unit is an all digital phase-locked loop (ADPLL) that multiplies a master clock signal, and
the frequency control unit includes
a correction coefficient holding unit that holds a predetermined number of correction coefficients,
a frequency control word generation unit that generates, based on the measurement value and the held correction coefficients, a frequency control word indicating a multiplication ratio of the ADPLL, and
a control circuit that updates the held correction coefficients based on the external measurement error.

5. The transmission device according to claim 4, wherein the measurement value includes at least one of a temperature, a power supply voltage, and a voltage or current value that indicates process information.

6. The transmission device according to claim 4, wherein
the measurement value includes an actual measurement frequency of the transmission clock signal measured on the transmission side, and
the control circuit sets initial values for the correction coefficients based on the actual measurement frequency.

7. The transmission device according to claim 4, wherein
the control circuit updates the held correction coefficients when the external measurement error is outside a predetermined range, and
the frequency control word generation unit updates the frequency control word when the correction coefficients are updated.

8. The transmission device according to claim 1, further comprising a startup oscillator that generates a predetermined startup clock signal when a startup signal from the reception device is detected,
wherein the frequency control unit controls the frequency in synchronization with the startup clock signal.

9. A transmission/reception system comprising:
a reception device that receives a transmission clock signal, generates a reception clock signal from the transmission clock signal, and measures an error in a frequency of the reception clock signal as an external measurement error; and
a transmission device that includes an error acquisition unit that acquires the external measurement error, a clock signal generation unit that generates a transmission clock signal, a transmission unit that transmits the transmission clock signal, and a frequency control unit that controls a frequency of the transmission clock signal based on the external measurement error and a measurement value measured on a transmission side.

10. The transmission/reception system according to claim 9, wherein
the transmission unit includes a first driver that embeds the transmission clock signal in data and transmits the data, and
the reception device includes
a third driver that receives the data, and
a clock data recovery circuit that extracts the transmission clock signal from the received data.

11. The transmission/reception system according to claim 9, wherein
the transmission unit includes
a first driver that transmits data, and
a second driver that transmits the transmission clock signal,
wherein
the reception device includes
a third driver that receives the data, and
a fourth driver that receives the transmission clock signal.

12. A method for controlling a transmission device, comprising:
a clock signal generation step of generating a transmission clock signal;
a transmission step of transmitting the transmission clock signal;
an error acquisition step of acquiring an external measurement error that is an error in a frequency of a reception clock signal measured by a reception device that receives the transmission clock signal and generates the reception clock signal from the transmission clock signal; and
a frequency control step of controlling a frequency of the transmission clock signal based on the external measurement error and a measurement value measured on a transmission side.
